(19) United States
(12) Patent Application Publication
(10) Pub. No.: US 2024/0157471 A1
(43) Pub. Date: May 16, 2024

(54) LASER ANNEALING DEVICE AND LASER ANNEALING METHOD

(71) Applicant: Panasonic Intellectual Property Management Co., Ltd., Osaka (JP)

(72) Inventors: MITSUOKI HISHIDA, Gifu (JP); HIROAKI SUZUKI, Osaka (JP)

(21) Appl. No.: 18/418,291

(22) Filed: Jan. 21, 2024

Related U.S. Application Data
(63) Continuation of application No. PCT/JP2022/026186, filed on Jun. 30, 2022.

(30) Foreign Application Priority Data
Sep. 2, 2021 (JP) 2021-143326

(51) Int. Cl. B23K 26/06; B23K 26/352

(52) U.S. Cl. CPC B23K 26/0608; B23K 26/0643; B23K 26/352

(57) ABSTRACT

Laser annealing device (1) irradiates amorphous silicon film (W1) with laser beam (Li) to perform an annealing process. The laser annealing device includes: a plurality of laser oscillators (2i) that emit laser beams having mutually different wavelengths (λi); diffraction grating (3) that diffracts the laser beams emitted from the laser oscillators; and controller (6) that switches on and off states of emission of the laser beams by the laser oscillators. The laser oscillators are disposed at mutually different positions, and the laser beams emitted from the laser oscillators are diffracted on identical optical axis (A) by the diffraction grating. The controller can select at least one or more of the laser oscillators for turning on emission of the laser beams from among the plurality of laser oscillators in accordance with any crystal grain size of the amorphous silicon film.

### TECHNICAL FIELD

The present disclosure relates to a laser annealing device and a laser annealing method.

### BACKGROUND ART

A laser annealing device forms a polysilicon film by irradiating an amorphous silicon film with a laser beam and performing an annealing process. For example, a laser annealing device disclosed in PTL 1 includes a laser light source configured to generate a plurality of light emission points at which a GaN-based semiconductor laser element emits a laser beam having a wavelength of 350 nm to 450 nm, a spatial light modulation element in which a large number of pixel portions whose light modulation states change in accordance with control signals are arranged on a substrate and which modulates the laser beam emitted from the laser light source, and a scanner which scans an annealing surface with the laser beam modulated in each pixel portion.

The laser light source includes a plurality of the GaN-based semiconductor laser elements, a condensing lens as a condensing optical system that condenses laser beams emitted from the plurality of GaN-based semiconductor laser elements and couples the condensed beams to an incident end of an optical fiber, and one optical fiber. As described above, the laser beams emitted from the plurality of GaN-based semiconductor laser elements are spatially synthesized by the condensing lens.

In addition, NPL 1 describes that by irradiating an amorphous silicon film with a laser beam by a blue laser diode having a wavelength of 445 nm, it is possible to form a high-quality polysilicon film having a fine grain size advantageous to uniformity as compared with a case of a XeCl excimer laser having a wavelength of 308 nm. In addition, it is described that the longer the wavelength of the laser beam is, the more difficult to absorb the beam is, and thus the penetration depth of the laser beam into the amorphous silicon film increases.

### CITATION LIST

### Patent Literatures

PTL 1: Unexamined Japanese Patent Publication No. 2004-064066 NPL 1: Yi Chen, “Research on Junction Formation Using Laser Annealing for High-Performance Si Power MOS FETs”, doctoral thesis of the University of the Ryukyus, September 2016, pp. 32 and 33

### SUMMARY OF THE INVENTION

### Technical Problem

Incidentally, in a step of irradiating the amorphous silicon film with the laser beam and performing the annealing process, even if the amorphous silicon film is irradiated on the same conditions, that is, with the laser beam having the same wavelength for the same time, the quality of the formed polysilicon film may vary.

Therefore, the present inventors have conceived changing the wavelength of the laser beam in accordance with any crystal grain size or the crystallinity of the amorphous silicon film. This makes it possible to appropriately adjust the absorption coefficient, the penetration depth, and the like of the laser beam with respect to the amorphous silicon film, which is advantageous in uniformly controlling the quality of the polysilicon film.

However, in a case where the above-described configuration in which the wavelength of the laser beam is changed in accordance with the crystal grain size of the amorphous silicon film is achieved by the spatial synthesis as in PTL 1, there is a physical problem that the irradiation position and the range of the laser beam with respect to the amorphous silicon film are changed because the laser beams are condensed from a plurality of the laser light sources disposed in mutually different positions, or the irradiation position and the range of the laser beam are changed due to the influence of optical characteristics such as the occurrence of a beam deviation angle difference when the light source wavelength is changed.

The present disclosure has been made in view of such a point, and an object of the present disclosure is to uniformly control the quality of a polysilicon film to be formed while suppressing a change in irradiation position and range of a laser beam with respect to an amorphous silicon film for each wavelength.

### Solution to Problem

A laser annealing device according to the present disclosure is a laser annealing device that irradiates an amorphous silicon film with a laser beam to perform an annealing process. The laser annealing device includes: a plurality of laser light sources that emit laser beams having mutually different wavelengths; a diffraction grating that diffracts the laser beams emitted from the laser light sources; and a controller that switches on and off states of emission of the laser beams by the laser light sources. The laser light sources are disposed at mutually different positions, and the laser beams emitted from the laser light sources are diffracted on an identical optical axis by the diffraction grating. The controller can select at least one or more of the laser light sources for turning on emission of the laser beams from among the plurality of laser light sources in accordance with any crystal grain size of the amorphous silicon film.

A laser annealing method according to the present disclosure is a laser annealing method of irradiating an amorphous silicon film with a laser beam to perform an annealing process. A plurality of laser light sources that emit laser beams having mutually different wavelengths are disposed at mutually different positions, and the laser beams are diffracted on an identical optical axis by a diffraction grating. At least one or more of the laser light sources for turning on emission of the laser beams are selected from among the plurality of laser light sources in accordance with any crystal grain size of the amorphous silicon film.

### Advantageous Effect of Invention

According to the present disclosure, it is possible to uniformly control the quality of the polysilicon film to be formed while suppressing a change in irradiation position and range of the laser beam with respect to the amorphous silicon film for each wavelength.

### BRIEF DESCRIPTION OF THE DRAWINGS

FIG. 1 is a diagram illustrating a laser annealing device by wavelength beam combining according to the present exemplary embodiment.

FIG. 2 is a graph illustrating a relationship between a wavelength of a laser beam and an absorption coefficient into an amorphous silicon film.

FIG. 3 illustrates a laser annealing device by spatial synthesis according to a conventional example.

### DESCRIPTION OF EMBODIMENT

Hereinafter, exemplary embodiments of the present disclosure will be described in detail with reference to the drawings. The following description of preferred exemplary embodiments is merely illustrative in nature and is not intended to limit the present disclosure, applications thereof, or uses thereof at all.

(Laser Annealing Device)

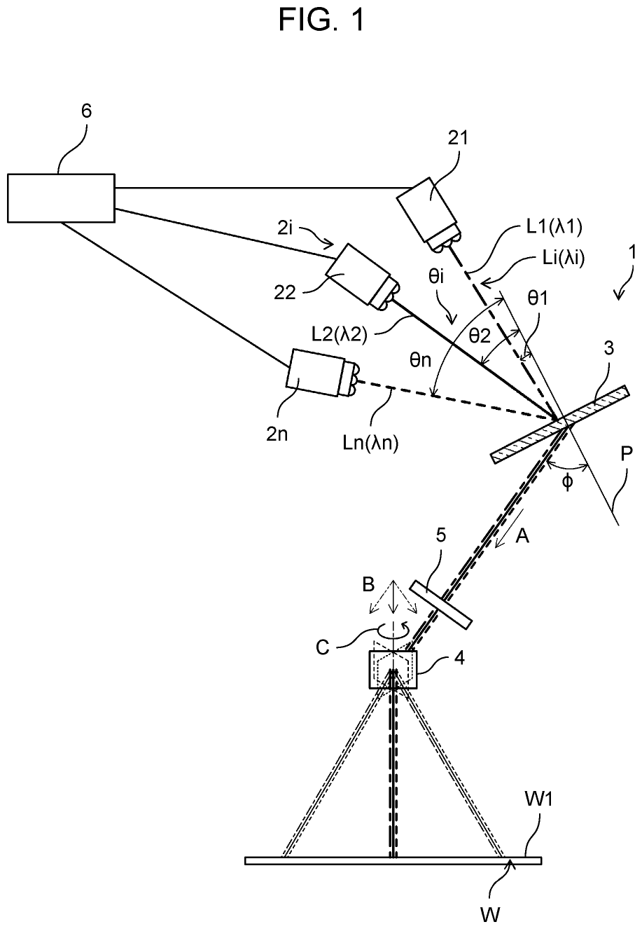

FIG. 1 illustrates laser annealing device 1. Laser annealing device 1 employs wavelength beam combining (WBC). Laser annealing device 1 forms a polysilicon film (crystallized film) by irradiating amorphous silicon film W1 deposited on a surface of substrate W with a laser beam and performing an annealing process. Amorphous silicon film W1 is formed as a precursor film.

As illustrated in FIG. 1, laser annealing device 1 includes a plurality of (n) laser oscillators (laser light sources) 2i (i=1, 2, . . . n), transmission type diffraction grating 3, galvanometer mirror 4, coupler 5, and controller 6. The number n of laser oscillators 2i is, for example, 12.

Each of laser oscillators 2i emits laser beam Li (i=1, 2, . . . n) having mutually different wavelength λi (i=1, 2, . . . n) toward diffraction grating 3 at incident angle θi (i=1, 2, . . . n). Incident angle θi is an angle formed by an incident light from each of laser oscillators 2i and normal line P of diffraction grating 3.

In FIG. 1, for simplicity, only first laser oscillator 21, second laser oscillator 22, and nth laser oscillator 2n are illustrated.

First laser oscillator 21 emits laser beam L1 having wavelength λ1 toward diffraction grating 3 at incident angle θ1. Second laser oscillator 22 emits laser beam L2 having wavelength λ2 toward diffraction grating 3 at incident angle θ2. Nth laser oscillator 2n emits laser beam Ln having wavelength λn toward diffraction grating 3 at incident angle θn.

The plurality of laser oscillators 2i include laser oscillator 2i that emits laser beam Li in a blue region, specifically, having wavelength λi between 435 nm and 460 nm (inclusive). In the present exemplary embodiment, wavelengths λi of all laser oscillators 2i range from 435 nm to 460 nm inclusive. Wavelength λ1 of first laser oscillator 21 is the shortest, 435 nm. Wavelength λn of nth laser oscillator 2n is the longest, 460 nm. N laser oscillators 2i divide a wavelength range from 435 nm to 460 nm inclusive into n.

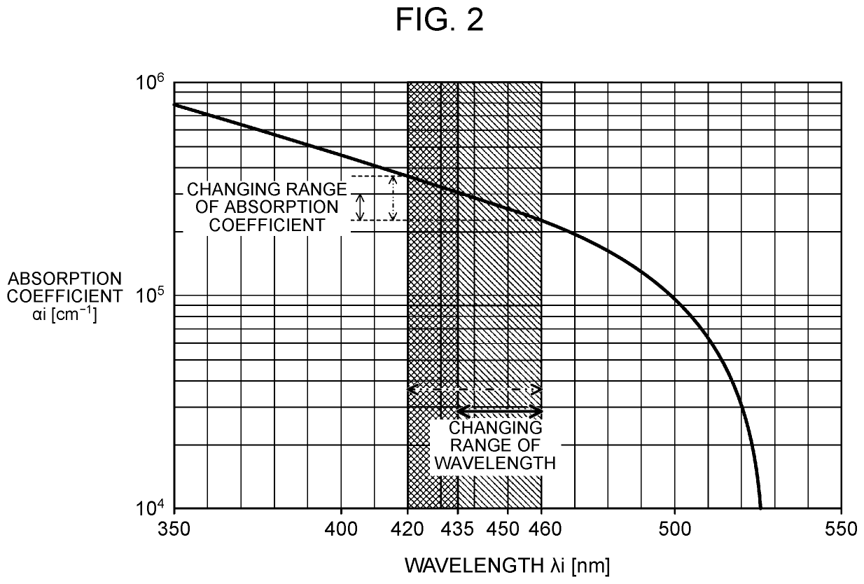

FIG. 2 is a graph illustrating a relationship between wavelength λi [nm] of laser beam Li and absorption coefficient αi [cm⁻¹] into amorphous silicon film W1. As illustrated in FIG. 2, absorption coefficient αi [cm⁻¹] decreases as wavelength λi [nm] increases.

As illustrated in FIG. 1, diffraction grating 3 transmits and diffracts each laser beam Li emitted from each laser oscillator 2i. Here, laser oscillators 2i are disposed at mutually different positions so that emitted laser beams Li are transmitted and diffracted on identical optical axis A by diffraction grating 3 (transmitted and diffracted at identical diffraction angle φ).

Diffraction angle φ is an angle formed by a diffracted light by diffraction grating 3 and normal line P of diffraction grating 3. Diffraction angle φ is set such that optical axis A obliquely intersects the surface of substrate W.

A relationship among period (opening spacing, not illustrated) d of transmission type diffraction grating 3, wavelength λi, incident angle θi, and diffraction angle φ illustrated in FIG. 1 is as follows. d(sin θi−sin φ)=mλi (m is an integer excluding zero).

Galvanometer minor 4 is interposed between amorphous silicon film W1 (substrate W) and diffraction grating 3. Galvanometer minor 4 irradiates amorphous silicon film W1 (substrate W) with laser beam Li diffracted by diffraction grating 3 and traveling on optical axis A in irradiation direction B.

The inclination of galvanometer mirror 4 can be changed by an actuator (not illustrated) including a motor, a piezoelectric element, or the like (see C in FIG. 1). Irradiation direction B of laser beam Li by galvanometer mirror 4 changes in accordance with a change in inclination of galvanometer mirror 4.

Coupler 5 is disposed between diffraction grating 3 and galvanometer mirror 4. A part (several percent) of laser beam Li emitted from laser oscillator 2i and diffracted by diffraction grating 3 is returned to laser oscillator 2i by coupler 5. Then, the part of laser beam Li reciprocates many times between laser oscillator 2i and coupler 5, whereby laser beam Li emitted from laser oscillator 2i is externally resonated. As a result, energy of laser beam Li is amplified.

Each of laser oscillators 2i is connected to controller 6. Controller 6 includes, for example, a microcomputer and a program. Controller 6 switches on and off states of emission of laser beam Li by each of laser oscillators 2i.

Here, in a monitoring step before a laser annealing step, a crystal grain size of amorphous silicon film W1 is measured. The crystal grain size is measured by various known methods. For example, the crystal grain size is observed by a scanning electron microscope (SEM) after a crystal grain boundary of amorphous silicon film W1 is actualized by a Secco etching process. In addition to the method of measuring the crystal grain size by the Secco etching process, there is also a method of evaluating crystallinity by X-ray diffraction, Raman spectroscopy, spectroscopic ellipsometry, electrical conductivity, or the like.

Controller 6 can optionally select at least one or more laser oscillators 2i for turning on emission of laser beams Li from among the plurality of laser oscillators 2i in accordance with any crystal grain size of amorphous silicon film W1. In other words, controller 6 can optionally select wavelength λi of laser beam Li with which amorphous silicon film W1 is irradiated from the wavelength range from 435 nm to 460 nm inclusive.

Here, while there are a plurality of crystal grains in amorphous silicon film W1, a user may optionally (freely) select a crystal grain to be used for determination of wavelength selection from among the plurality of crystal grains. As a size of a crystal grain, for example, a diameter (crystal grain size) and a surface area of the crystal grain may be appropriately adopted.

In the example of FIG. 1, controller 6 may turn on only emission of laser beam L1 by first laser oscillator 21 and turn off emission of laser beams L2, Ln by second laser oscillator 22 and nth laser oscillator 2n. That is, controller 6 may select only wavelength λ1 and may not select wavelength λ2 or wavelength λn from the wavelength range from 435 nm to 460 nm inclusive.

Further, controller 6 may turn on emission of laser beams L1, L2 by first laser oscillator 21 and second laser oscillator 22 and turn off emission of laser beam Ln by nth laser oscillator 2n. That is, controller 6 may select wavelength λ1 and wavelength λ2 and may not select wavelength λn from the wavelength range from 435 nm to 460 nm inclusive.

Further, controller 6 may turn on emission of laser beams L1, L2, . . . Ln by all laser oscillators 21, 22, . . . 2n. That is, controller 6 may select all wavelengths λ1, λ2, . . . λn from the wavelength range from 435 nm to 460 nm inclusive.

Controller 6 may select a combination of wavelengths λi other than those exemplified above.

### Operation and Effect

According to the present exemplary embodiment, by appropriately selecting wavelength λi of laser beam Li with which amorphous silicon film W1 is irradiated in accordance with the crystal grain size of amorphous silicon film W1, absorption coefficient αi, a penetration depth, and the like of laser beam Li into amorphous silicon film W1 can be appropriately adjusted. This is advantageous in uniformly controlling the quality of the polysilicon film to be formed.

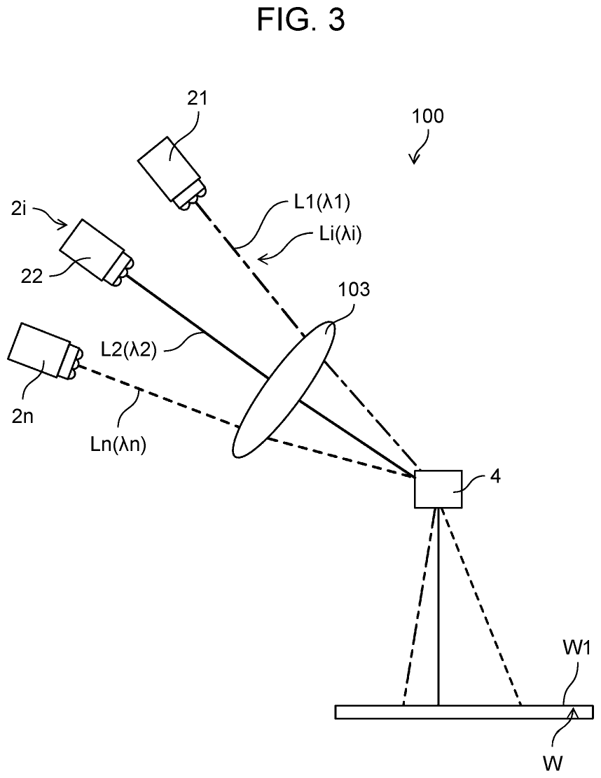

Here, FIG. 3 illustrates laser annealing device 100 according to a conventional example. Laser annealing device 100 according to the conventional example includes condensing lens 103 instead of diffraction grating 3. Laser beams Li emitted from laser oscillators 2i are condensed (spatially synthesized) by condensing lens 103, and then emitted toward amorphous silicon film W1 by galvanometer mirror 4. Other configurations are similar to those of laser annealing device 1 according to the present exemplary embodiment.

In laser annealing device 100 according to the conventional example, since an arrangement position and wavelength λi of each laser oscillator 2i are mutually different, laser beam Li condensed (spatially synthesized) by condensing lens 103 and emitted by galvanometer mirror 4 is emitted to a position different for each wavelength λi of amorphous silicon film W1 as illustrated in FIG. 3.

On the other hand, in laser annealing device 1 according to the present exemplary embodiment, as illustrated in FIG. 1, laser beam Li diffracted by diffraction grating 3 and emitted by galvanometer mirror 4 is emitted to an identical position and range of amorphous silicon film W1 regardless of wavelength λi.

As described above, it is possible to uniformly control the quality of the polysilicon film to be formed while suppressing a change in irradiation position and range of laser beam Li with respect to amorphous silicon film W1 for each wavelength λi.

In particular, by selecting wavelength λi from the blue region, specifically, the wavelength range from 435 nm to 460 nm inclusive, amorphous silicon film W1 can be irradiated with laser beam Li having small absorption coefficient αi as illustrated in FIG. 2. By reducing absorption coefficient αi to some extent, a penetration depth of laser beam Li into amorphous silicon film W1 can be increased. This makes it easier to control the quality of the polysilicon film to be formed as compared with a case of a region having a low wavelength (for example, a 308 nm XeCl excimer laser).

By changing the inclination of galvanometer mirror 4, a wide region of amorphous silicon film W1 can be easily irradiated with laser beam Li.

### Other Exemplary Embodiments

Although the present disclosure has been described above with the suitable exemplary embodiment, the present disclosure is not limited to the above description, and various modifications can be surely made.

Galvanometer minor 4 may be omitted. For example, a cylindrical lens may be provided between amorphous silicon film W1 and diffraction grating 3. The cylindrical lens can linearly increase a spot diameter of laser beam Li. In this case, a minor that changes a traveling direction of laser beam Li may be disposed between the cylindrical lens and diffraction grating 3.

Furthermore, laser annealing device 1 may include a movement mechanism (not illustrated). The movement mechanism moves (changes the position of) substrate W on the surface of which amorphous silicon film W1 is deposited. The movement mechanism is, for example, a movable stage on which substrate W is placed. By moving substrate W by the movement mechanism, a wide region of amorphous silicon film W1 can be irradiated with laser beam Li even without galvanometer mirror 4.

In the above exemplary embodiment, transmission type diffraction grating 3 is used, but the present disclosure is not limited thereto. Diffraction grating 3 may be a reflection type.

Although not illustrated in the above exemplary embodiment (particularly FIG. 1), an FAC lens, a twister lens, a prism lens, or the like may be provided between laser oscillator 2i and diffraction grating 3 or between diffraction grating 3 and coupler 5 in order to allow laser beam Li to efficiently enter.

The wavelength range is not limited to the range from 435 nm to 460 nm inclusive. For example, the lower limit may be extended to a range from 420 nm to 460 nm inclusive. Furthermore, the wavelength range may not include the blue region, and may be, for example, an ultraviolet region (less than or equal to 400 nm).

A laser annealing method according to the present disclosure is a laser annealing method of irradiating amorphous silicon film W1 with laser beam Li to perform an annealing process. A plurality of laser oscillators 2i that emit laser beams Li having mutually different wavelengths λi are disposed at mutually different positions, and laser beams Li are diffracted on identical optical axis A by diffraction grating 3. At least one or more laser oscillators 2i for turning on emission of laser beams Li are selected from among the plurality of laser oscillators Li in accordance with any crystal grain size of amorphous silicon film W1.

### INDUSTRIAL APPLICABILITY

Since the present disclosure can be applied to the laser annealing device and the laser annealing method, the present disclosure is extremely useful and has high industrial applicability.

### REFERENCE MARKS IN THE DRAWINGS

A optical axis
B irradiation direction
C inclination
P normal line
W substrate
W1 amorphous silicon film
λi wavelength
Li laser beam
θi incident angle
φ diffraction angle
1 laser annealing device
2i laser oscillator (laser light source)
3 diffraction grating
4 galvanometer minor
5 coupler
6 controller

1. A laser annealing device that irradiates an amorphous silicon film with a laser beam to perform an annealing process, the laser annealing device comprising:
a plurality of laser light sources that emit laser beams having mutually different wavelengths;
a diffraction grating that diffracts the laser beams emitted from the laser light sources; and
a controller that switches on and off states of emission of the laser beams by the laser light sources,
wherein the laser light sources are disposed at mutually different positions, and the laser beams emitted from the laser light sources are diffracted on an identical optical axis by the diffraction grating, and
the controller selects at least one or more of the laser light sources for turning on emission of the laser beams from among the plurality of laser light sources in accordance with any crystal grain size of the amorphous silicon film.

2. The laser annealing device according to claim 1, wherein
the plurality of laser light sources include the laser light source that emits the laser beam having a wavelength between 420 nm and 460 nm (inclusive), and
the controller selects a wavelength of the laser beam emitted to the amorphous silicon film from a wavelength range from 420 nm to 460 nm inclusive.

3. The laser annealing device according to claim 1, further comprising a minor interposed between the amorphous silicon film and the diffraction grating, the mirror irradiating the amorphous silicon film with the laser beam and having a changeable inclination.

4. The laser annealing device according to claim 1, further comprising a movement mechanism that moves a substrate on which the amorphous silicon film is deposited.

5. A laser annealing method of irradiating an amorphous silicon film with a laser beam to perform an annealing process, the method comprising:
disposing a plurality of laser light sources that emit laser beams having mutually different wavelengths at mutually different positions, the laser beams being diffracted on an identical optical axis by a diffraction grating; and
selecting at least one or more of the laser light sources for turning on emission of the laser beams from among the plurality of laser light sources in accordance with any crystal grain size of the amorphous silicon film.
